(19) United States
(12) Patent Application Publication
(10) Pub. No.: US 2010/0096711 A1
(43) Pub. Date: Apr. 22, 2010

(54) MICROELECTROMECHANICAL SYSTEM MICROPHONE PACKAGE

(75) Inventor: Jyong-Yue TIAN, Tanzih Township (TW)

Correspondence Address: BROWDY AND NEIMARK, P.L.L.C.;624 NINTH STREET, NW, SUITE 300, WASHINGTON, DC, 20001-5303, US

(73) Assignee: LINGSEN PRECISION INDUSTRIES, LTD., T.E.P.Z. Taichung (TW)

(21) Appl. No.: 12/277,121

(22) Filed: Nov. 24, 2008

(30) Foreign Application Priority Data
Oct. 16, 2008 (TW) 97218507

(51) Int. Cl. H01L 29/84

(52) U.S. Cl. 257/415; 257/E29.324

(57) ABSTRACT

An MEMS microphone package includes a substrate, a cover, a plurality of conductive members, and an insulative adhesive. The cover is mounted to the substrate. The conductive members are disposed between the substrate and the cover. Each of the conductive members can be a golden wire, a conductive bump, or a conductive metal. Upper ends of the conductive members are connected with the cover and the lower ends of the conductive members are connected with the substrate to enable a conductive loop. The insulative adhesive encapsulates the conductive members. In this way, the substrate, the conductive members, and the cover jointly construct a shielding against EMI.

### BACKGROUND OF THE INVENTION

1. Field of the Invention

The present invention relates generally to integrated circuit (IC) packages, and more particularly, to a microelectromechanical system (MEMS) microphone package.

2. Description of the Related Art

As the technology develops quickly, a variety of new and innovative products keep presented. To satisfy the consumers' requirement for convenient operation and portability, the electronic products are researched and developed to be lightweight, thin, short, and small. Among those electronic products, the MEMS microphone is very popular.

A typical MEMS microphone was disclosed by U.S. Pat. No. 6,781,231 filed by Knowles Electronics and entitled “MEMS SYSTEM PACKAGE WITH ENVIRONMENTAL AND INTERFERENCE SHIELD”, which is composed of an MEMS system microphone, a substrate, and a cover. An end edge of an opening of the cover is electrically connected with the substrate by an electrically conductive material, like conductive adhesive or solder.

However, the conductive adhesive or the solder tends to be coated excessively, during sealing the opening, to overflow into the substrate within the cover, thus causing short circuit of electronic components on the substrate. Besides, such electrically conductive material is high-cost because of its complicated production process. Such electrically conductive material is also less adhesive than the general insulative adhesive to have less durability.

### SUMMARY OF THE INVENTION

The primary objective of the present invention is to provide an MEMS microphone package, which can effectively enhance the packaging yield and lower the cost for its product.

The foregoing objective of the present invention is attained by the MEMS microphone package composed of a substrate, a cover, a plurality of conductive members, and an insulative adhesive. The cover is mounted to the substrate. The conductive members are disposed between the substrate and the cover. Each of the conductive members can be a golden wire, a conductive bump, or a conductive metal, having a upper end and a lower end. The upper ends of the conductive members are connected with the cover and the lower ends of the conductive members are connected with the substrate to enable a conductive loop. The insulative adhesive encapsulates the conductive members. In this way, the substrate, the conductive members, and the cover jointly construct a shielding against electromagnetic interference (EMI).

### BRIEF DESCRIPTION OF THE DRAWINGS

FIG. 1 is a top view of a first preferred embodiment of the present invention from which the cover is removed, illustrating that the golden wires and the insulative adhesive are disposed at the peripheral edge of the substrate.

FIG. 2 is a sectional view of the first preferred embodiment of the present invention, illustrating that the substrate and the cover are electrically connected with each other by the golden wires.

FIG. 3 is a sectional view of a second preferred embodiment of the present invention, illustrating that the substrate and the cover are electrically connected with each other by the conductive bumps.

### DETAILED DESCRIPTION OF PREFERRED EMBODIMENTS

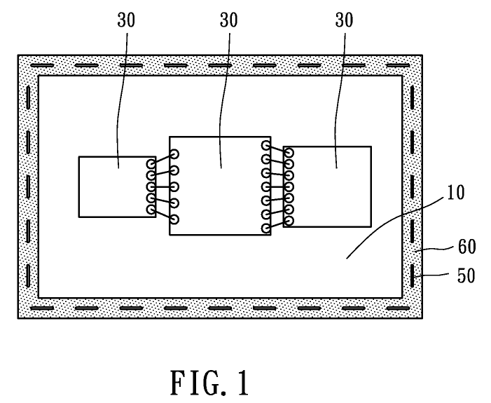

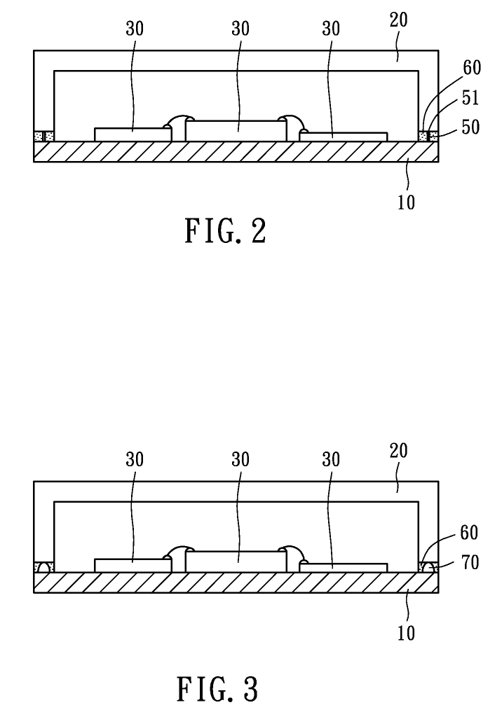

Referring to FIGS. 1 and 2, an MEMS microphone constructed according to a first preferred embodiment of the present invention is composed of a substrate 10, a cover 20 mounted to the substrate 10, and a plurality of electronic components 30, like sensor chips or passive components, located on the substrate 10. A conductive material layer is disposed at a peripheral edge of the substrate 10. Another conductive material layer is disposed on a surface of the cover 20. Because the present invention is focused on the package of the substrate 10 and the cover 20, the relevant operation of the electronic components 30 will not be recited thereafter.

During the IC packaging of the present invention, a plurality of golden wires 50, each of which has an arc tip having the same height, are firstly mounted to where the substrate 10 and the cover 20 contact each other by wire bonding, surrounding the periphery of the substrate 10. Next, an insulative adhesive 60 fully encapsulates the golden wires 50 therein. When the cover 20 is aligned with the substrate 10 to be butted with each other for a squeezing and packaging operation, the golden wires 50 have proper rigidity, after the wire bonding, and the insulative adhesive 60 is not completely solidified, even if the arc tips 51 of the golden wires 50 still have little amount of the insulative adhesive 60, the insulative adhesive 60 will still be squeezed to flow sideward, such that the base periphery of the cover 20 will contact the arc tips 51 of the golden wires 50. When upper and lower ends of the golden wires 50 are connected with the cover 20 and the substrate 10 respectively, a conductive loop is constructed and then the substrate 10, the golden wires 50, and the cover 20 jointly form a shielding against the EMI.

Referring to FIG. 3, an MEMS microphone constructed according to a second preferred embodiment of the present invention is similar to the first embodiment, having the difference lies in that a plurality of conductive bumps 70 are formed on where the substrate 10 contacts the cover 20 and an insulative adhesive 60 totally encapsulates the conductive bumps 70. When the cover 20 is aligned with the substrate 10 to be butted with each other for the squeezing and packaging operation, the conductive bumps 70 have proper rigidity and the insulative adhesive 60 is not completely solidified, even if tips of the conductive bumps 70 still have little amount of the insulative adhesive 60, the insulative adhesive 60 will still be squeezed to flow sideward, such that the base periphery of the cover 20 will contact the tips of the conductive bumps 70. When upper and lower ends of the conductive bumps 70 are connected with the cover 20 and the substrate 10, a conductive loop is constructed and then the substrate 10, the conductive bumps 70, and the cover 20 jointly form a shielding against the EMI.

It is to be noted that when the cover 20 is aligned with the substrate 10 to be butted with each other for the squeezing and packaging operation, the golden wires 50 or the conductive bumps 70 are fully encapsulated inside the insulative adhesive 60, such that only the insulative adhesive 60 are exposed outside. Even if the insulative adhesive 60 around the golden wires 50 or the conductive bumps 70 happens to overflow sideward into a receiving space between the cover 20 and the substrate 10, the insulative adhesive 60 will not have short circuit with the electronic components 30. In other words, the present invention will not cause that the conductive material is coated too much to overflow into the substrate within the cover to cause short circuit of the electronic components on the substrate as the prior art did. Therefore, the present invention provides the conductive loop avoiding the EMI and also prevents the substrate from short circuit, effectively enhancing the packaging yield. Besides, the present invention is applied with the inexpensive insulative adhesive 60 rather than the expensive conductive adhesive to have low production cost, and the insulative adhesive is more adhesive and durable than the conductive adhesive.

Although the present invention has been described with respect to specific preferred embodiments thereof, it is no way limited to the details of the illustrated structures but changes and modifications may be made within the scope of the appended claims.

What is claimed is:

1. An MEMS microphone comprising:
a substrate;
a cover mounted to the substrate;
a plurality of conductive members disposed at where said substrate contacts said cover, each of said conductive members having an upper end and a lower end, upper ends of said conductive members being connected with said cover, lower ends of said conductive members being connected with said substrate; and
an insulative adhesive encapsulating said conductive members;
wherein said substrate, said conductive members, and said cover jointly form a shielding against EMI.

2. The MEMS microphone as defined in claim 1, wherein each of said conductive members is a golden wire, a conductive bump, or a conductive metal.
